(19) United States
(12) Patent Application Publication
(10) Pub. No.: US 2016/0260636 A1
(43) Pub. Date: Sep. 8, 2016

(54) METHOD FOR FABRICATING SEMICONDUCTOR DEVICE

(71) Applicant: UNITED MICROELECTRONICS CORP., Hsin-Chu City (TW)

(72) Inventor: Chien-Ting Lin, Hsinchu City (TW)

(21) Appl. No.: 14/672,255

(22) Filed: Mar. 30, 2015

(30) Foreign Application Priority Data
Mar. 3, 2015 (CN) 201510093659.0

(51) Int. Cl. H01L 21/8234; H01L 29/78; H01L 21/762; H01L 29/06; H01L 21/306; H01L 21/308

(52) U.S. Cl. CPC H01L 21/823412; H01L 21/30604; H01L 21/3085; H01L 21/76232; H01L 21/823481; H01L 21/823431; H01L 29/0649; H01L 29/7851

(57) ABSTRACT

A method for fabricating semiconductor device is disclosed. The method includes the steps of: providing a substrate having a first region, a second region, and a third region defined thereon; forming a plurality of fin-shaped structures on the first region, the second region, and the third region of the substrate; performing a first fin-cut process to form a first fin-shaped structure on the first region, a second fin-shaped structure on the second region, and a third fin-shaped structure on the third region, wherein the height of the first fins-shaped structure is different from the heights of the second fin-shaped structure and the third fin-shaped structure; and performing a second fin-cut process to lower the height of the third fin-shaped structure.

### BACKGROUND OF THE INVENTION

1. Field of the Invention

The invention relates to a method for fabricating semiconductor device, and more particularly, to a method of using two fin-cut processes to form fin-shaped structures of different heights.

2. Description of the Prior Art

With increasing miniaturization of semiconductor devices, it is crucial to maintain the efficiency of miniaturized semiconductor devices in the industry. However, as the size of the field effect transistors (FETs) is continuously shrunk, the development of the planar FETs faces more limitations in the fabricating process thereof. On the other hand, non-planar FETs, such as the fin field effect transistor (Fin FET) have three-dimensional structure, not only capable of increasing the contact to the gate but also improving the controlling of the channel region, such that the non-planar FETs have replaced the planar FETs and become the mainstream of the development.

The current method of forming the Fin FETs is forming a fin structure on a substrate primary, and then forming a gate on the fin structure. The fin structure generally includes the stripe-shaped fin formed by etching the substrate. However, under the requirements of continuous miniaturization, the width of each fin, as well as the pitch between fins have to be shrunk accordingly. Thus, the fabricating process of the Fin FETs also faces more challenges and limitations. For example, the fabricating process is limited by current mask and lithography techniques, such that it has problems to precisely define the position of the fin structure, or to precisely control the etching time, thereby leading to fin collapse or over-etching issues, and seriously affecting the efficiency of the fin structure.

### SUMMARY OF THE INVENTION

According to a preferred embodiment of the present invention, a method for fabricating semiconductor device is disclosed. The method includes the steps of: providing a substrate having a first region, a second region, and a third region defined thereon; forming a plurality of fin-shaped structures on the first region, the second region, and the third region of the substrate; performing a first fin-cut process to form a first fin-shaped structure on the first region, a second fin-shaped structure on the second region, and a third fin-shaped structure on the third region, wherein the height of the first fins-shaped structure is different from the heights of the second fin-shaped structure and the third fin-shaped structure; and performing a second fin-cut process to lower the height of the third fin-shaped structure.

According to another aspect of the present invention, a semiconductor device is disclosed. The semiconductor device includes: a substrate having a first region, a second region, and a third region defined thereon; and a first fin-shaped structure on the first region, a second fin-shaped structure on the second region, and a third fin-shaped structure on the third region. Preferably, the heights of the first fin-shaped structure, the second fin-shaped structure, and the third fin-shaped structure are different.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating semiconductor device according to a preferred embodiment of the present invention.

### DETAILED DESCRIPTION

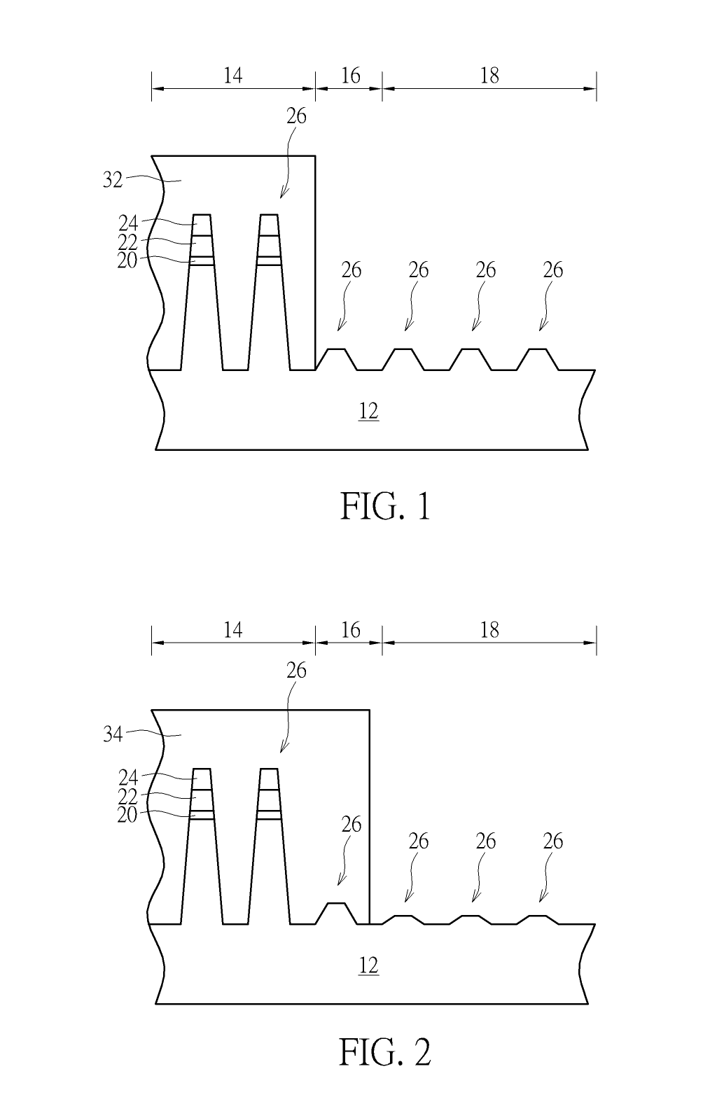

Referring to FIGS. 1-5, FIGS. 1-5 illustrate a method for fabricating semiconductor device according to a preferred embodiment of the present invention. As shown in FIG. 1, a substrate 12, such as silicon substrate is provided, and a first region 14, a second region 16, and a third region 18 are defined on the substrate 12. In this embodiment, the first region 14 is preferably used for fabricating elements used in real devices so that gate structures will be formed on fin-shaped structures of this region 14 thereafter. The second region 16 and third region 18 on the other hand are defined as dummy regions so that fin-shaped structures formed in these two regions 16 and 18 are preferably be used as dummy fin-shaped structures.

Next, a hard mask is formed on the substrate 12, in which the hard mask could be a single layered or multi-layered structure including a pad oxide layer 20, a pad nitride layer 22, and an oxide layer 24. A patterned mask (not shown) is then formed on the oxide layer 24, and an etching process is conducted to remove part of the oxide layer 24, part of the pad nitride layer 22, part of the pad oxide layer 20, and part of the substrate 12 to transfer the pattern of the patterned mask to the substrate 12 for forming a plurality of fin-shaped structures 26 on the first region 14, second region 16, and third region 18. In this embodiment, two fin-shaped structures 26 are formed on first region 14, one fin-shaped structure 26 is formed on second region 16, and three fin-shaped structures 26 are formed on third region 18, the quantity of the fin-shaped structures 26 is not limited to the ones discloses in this embodiment, but could be adjusted according to the demand of the process.

In addition, the fin-shaped structures 26 could also be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers maybe stripe-shaped. Subsequently, a deposition process and an etching process are carried out such that spacers are formed on the sidewalls of the patterned sacrificial layers. In a next step, patterned sacrificial layers can be removed completely and an etching process is conducted to transfer the pattern of the spacers to the oxide layer, pad nitride layer, pad oxide layer, and substrate to form desirable fin-shaped structures. It should be noted that the fin-shaped structures at this stage are preferably circular shaped fin-shaped structures instead of stripe-shaped fin-shaped structures.

Next, a first fin-cut process is conducted by first forming a patterned mask 32 such as patterned resist on the first region 14 and covering part of the fin-shaped structures 26, and an etching process is conducted to remove part of the fin-shaped structures 26 on first region 14, part of the fin-shaped structures 26 on second region 16, and part of the fin-shaped structures 26 on third region 18 so that the circular shaped or patterned fin-shaped structures 26 on first region 14 are cut into plurality of stripe-shaped fin-shaped structures 26 independent from each other while all the fin-shaped structures 26 on second region 16 and third region 18 are etched to have heights substantially lower than the height of the fin-shaped structures 26 on first region 14. Preferably, the height of the fin-shaped structures 26 on second region 16 is substantially equivalent to the height of the fin-shaped structures 26 on third region 18 at this stage.

Next, as shown in FIG. 2, the patterned mask 32 is stripped and a second fin-cut process is conducted by first forming another patterned mask 34 on the first region 14 and second region 16, and then conducting an etching process to remove part of the fin-shaped structures 26 on third region 18 so that the height of the fin-shaped structures 26 on third region 18 is less than the heights of fin-shaped structures 26 on both first region 14 and second region 16.

It should be noted that according to an embodiment of the present invention, as shown in FIG. 3, the heights of the substrate 12 and the fin-shaped structures 26 on third region 18 could be adjusted during the aforementioned second fin-cut process such that after the fin-shaped structures 26 on third region 18 are lowered by etching process, part of the substrate 12 could be further etched so that both top surfaces of the substrate 12 and fin-shaped structures 26 on third region 18 are lower than the substrate 12 surface of first region 14 and second region 16, which is also within the scope of the present invention.

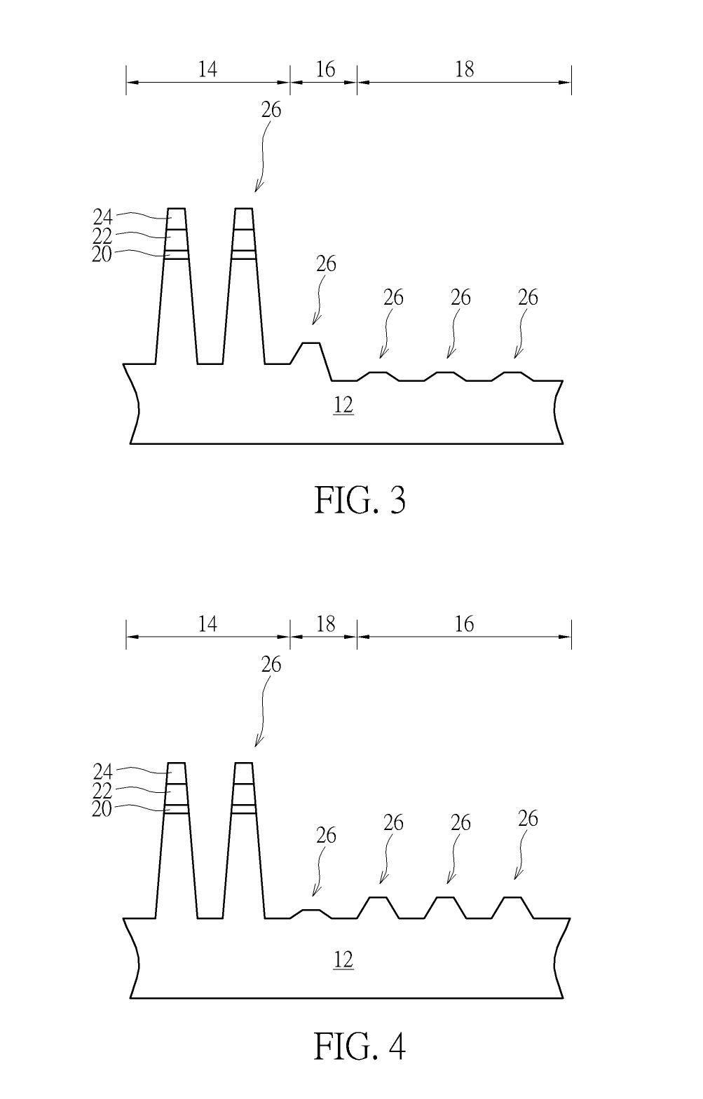

In addition, as shown in FIG. 4, in contrast to the aforementioned embodiment of forming the second region 16 immediately adjacent to the first region 14, it would also be desirable to form the third region 18 immediately adjacent to the first region 14 while the second region 16 is formed adjacent to the third region 18, and after two fin-cut processes are conducted, the height of fin-shaped structures 26 on third region 18 immediately adjacent to the first region 14 would be lower than the heights of fin-shaped structure 26 on both first region 14 and second region 16.

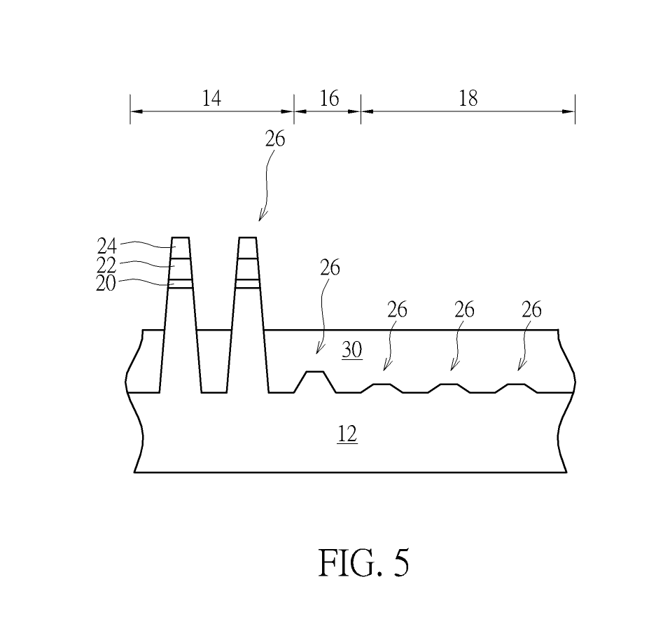

Next, as shown in FIG. 5, a shallow trench isolation (STI) formation process is conducted by first forming an insulating layer (not shown) composed of silicon oxide on the substrate 12 and covering the fin-shaped structures 26 on first region 14, second region 16, and third region 18, and then conducting a chemical mechanical polishing (CMP) and/or etching process to remove part of the insulating layer to form a STI 30. Preferably, the top surface of the STI 30 is lower than the tip of the fin-shaped structures 26 on first region 14 but completely covering the fin-shaped structures 26 on second region 16 and third region 18, or that the fin-shaped structures 26 of first region 14 is protruding from the STI 30. Next, a typical FinFET or nanowire fabrication process could be conducted by forming gate structure on the fin-shaped structures 26 of first region 14 and forming a source/drain region in the substrate 12 adjacent to two sides of the gate structure. It should be noted that a liner (not shown) composed of silicon oxide could be formed on the fin-shaped structures 26 surface of first region 14, second region 16, and third region 18 before the formation of STI 30, and the removal of the hard mask (including the pad oxide layer 20, pad nitride layer 22, and oxide layer 24) could be conducted before, in between, or after the first fin-cut process, second fin-cut process, and formation of STI 30.

Referring again to FIG. 5, FIG. 5 illustrates a structural view of a semiconductor device according to an embodiment of the present invention. As shown in FIG. 5, the semiconductor device includes a substrate 12, a first region 14, a second region 16 and a third region 18 defined on the substrate 12, and a plurality of fin-shaped structures 26 disposed on the first region 14, second region 16, and third region 18. Preferably, the fin-shaped structures 26 on first region 14, second region 16, and third region 18 include different heights.

More specifically, the heights of fin-shaped structures 26 on second region 16 and third region 18 are all lower than the height of fin-shaped structures 26 on first region 14 while the height of fin-shaped structures 26 on third region 18 is also lower than the height of fin-shaped structures 26 on second region 16. A STI 30 is also disposed on the substrate 12, in which the top surface of the STI 30 is preferably lower than the top surface of fin-shaped structures 26 on first region 14 but completely covering the fin-shaped structures 26 on second region 16 and third region 18.

Overall, the present invention preferably conducts two fin-cut processes after fin-shaped structures are formed on substrate so that the fin-shaped structures on different region of the substrate could have different heights. More specifically, the first fin-cut process preferably defines the fin-shaped structures on the substrate into two different heights as the second fin-cut process further lowers the height of part of the fin-shaped structures so that the fin-shaped structures on the substrate could have at least three different heights in total. By using the aforementioned approach it would be desirable to prevent unwanted impurities grown on the substrate and damages caused to non-dummy fin-shaped structures.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
providing a substrate having a first region, a second region, and a third region defined thereon;
forming a plurality of fin-shaped structures on the first region, the second region, and the third region of the substrate;
performing a first fin-cut process to form a first fin-shaped structure on the first region, a second fin-shaped structure on the second region, and a third fin-shaped structure on the third region, wherein the height of the first fins-shaped structure is different from the heights of the second fin-shaped structure and the third fin-shaped structure; and
performing a second fin-cut process to lower the height of the third fin-shaped structure.

2. The method of claim 1, wherein the first fin-cut process further comprises:
forming a patterned mask on the first region; and
performing an etching process to remove part of the second fin-shaped structure and part of the third fin-shaped structure so that the heights of the second fin-shaped structure and the third fin-shaped structure are lower than the height of the first fin-shaped structure.

3. The method of claim 2, wherein the heights of the second fin-shaped structure and the third fin-shaped structure are equivalent to each other.

4. The method of claim 1, wherein the second fin-cut process comprises:
forming a patterned mask on the first region and the second region; and
performing an etching process to remove part of the third fin-shaped structure so that the height of the third fin-shaped structure is lower than the heights of the first fin-shaped structure and the second fin-shaped structure.

5. The method of claim 1, further comprising forming a shallow trench isolation (STI) on the substrate to cover the second fin-shaped structure and the third fin-shaped structure.

6. The method of claim 5, wherein the top surface of the STI is lower than the top surface of the first fin-shaped structure.

7. A semiconductor device, comprising:
a substrate having a first region, a second region, and a third region defined thereon;
a first fin-shaped structure on the first region, a second fin-shaped structure on the second region, and a third fin-shaped structure on the third region, wherein the heights of the first fin-shaped structure, the second fin-shaped structure, and the third fin-shaped structure are different and the first fin-shaped structure, the second fin-shaped structure, and the third fin-shaped structure comprise same material; and
a shallow trench isolation (STI) on the substrate to cover the second fin-shaped structure and the third fin-shaped structure while the second fin-shaped structure and the third fin-shaped structure comprise different heights.

8. The semiconductor device of claim 7, wherein the heights of the second fin-shaped structure and the third fin-shaped structure are lower than the height of the first fin-shaped structure.

9. (canceled)

10. The semiconductor device of claim 7, wherein the top surface of the STI is lower than the top surface of the first fin-shaped structure.
